(19) United States
(12) Patent Application Publication
(10) Pub. No.: US 2015/0060955 A1
(43) Pub. Date: Mar. 5, 2015

(54) INTEGRATED MEMS MICROPHONE WITH MECHANICAL ELECTRICAL ISOLATION

(71) Applicant: WindTop Technology Corp., Hsinchu City (TW)

(72) Inventor: Kun-Lung Chen, Hsinchu City (TW)

(73) Assignee: WindTop Technology Corp., Hsinchu City (TW)

(21) Appl. No.: 14/016,297

(22) Filed: Sep. 3, 2013

(51) Int. Cl. B81B 3/00; B81C 1/00

(52) U.S. Cl. CPC B81B 3/0021; B81C 1/00158
USPC 257/254; 438/53

(57) ABSTRACT

An integrated MEMS microphone is provided, including, a bonding wafer layer, a bonding layer, an aluminum layer, CMOS substrate layer, an N+ implant doped silicon layer, a field oxide (FOX) layer, a plurality of implant doped silicon areas forming CMOS wells, a two-tier polysilicon layer with selective ion implantation forming a diaphragm, a plurality of implant doped silicon areas forming CMOS source/drain, a gate poly layer forming CMOS transistor gates, said CMOS wells, said CMOS transistor sources/drains and said CMOS gates forming CMOS transistors, an oxide layer embedded with an interconnect contact layer, a plurality of metal layers interleaved with a plurality of via hole layers, a Nitride deposition layer, an under bump metal (UBM) layer and a plurality of solder spheres. Diaphragm is sandwiched between a small top chamber and a small back chamber, and substrate layer includes a large back chamber.

### FIELD OF THE INVENTION

The present invention generally relates to an integrated MEMS device, and more specifically to an integrated MEMS device built with CMOS process, Flip Chip package and wafer bonding technology with mechanical/electrical isolation capability. The present invention provides the advantages of mechanical protection of the diaphragm from damage due to extreme environmental conditions, diaphragm stress relief with CMOS well drive-in by using Deep Trench Oxide (DTO) process, and small die size by Large Block Oxide Etch in MEMS area (LBOEM) process.

### BACKGROUND OF THE INVENTION

MEMS devices have long been attracting attentions due to a wide range of portable applications. For example, MEMS microphone has recently gained attraction due to the use of portable devices such as smart phones, tablet and notebook computers. Also, widely used are in the devices which require noise cancellation due to the MEMS microphone device-device uniformity. However, most of the MEMS microphones were made with separate MEMS sensors and ASIC circuits with the final products assembled by wire bonding on top of a PCB substrate. Some MEMS microphones were made with single chip without wire bonding using top metal film as MEMS diaphragms.

FIG. 1 shows a schematic view of a conventional structure of a MEMS microphone with two-chip structure. As shown in FIG. 1, a two-chip structure of a MEMS microphone includes a printed circuit board (PCB) 101 used as a base, a plurality of pads 102, a CMOS circuit 103, an epoxy 104 covering CMOS 103, a MEMS circuit 105 further including a diaphragm 105a and a back plate 105b, a wall 106 for encompassing the entire structure, a plurality of wire bonds 107, a lid 108 and a sound hole 109 for the sound to pass through. As shown in FIG. 1, a conventional two-chip MEMS microphone requires wire bonding and complex packaging, such as, a wall, a lid as well as a sound hole in the lid.

The problem with the two-chip solutions using wire bonding is that the wire is basically an inductive antenna and can pickup high frequency noise whose harmonics at low frequency band interferes with the sound in its frequency range. The problem with the above mentioned single-chip with metal composite film as diaphragm is long term reliability concern due to film instability when gone through temperature cycles. The other drawbacks of the above methods are high cost due to packaging. Thus, it is imperative to devise a MEMS microphone having high reliability and at the same time having low cost.

### SUMMARY OF THE INVENTION

The present invention has been made to overcome the above-mentioned drawbacks of conventional technologies for manufacturing MEMS microphone. The primary object of the present invention is to provide an integrated MEMS device by using flip-chip wafer level package (WLP) and selective ion implantation techniques for electrical/mechanical isolation.

Another object of the present invention is to provide an integrated MEMS microphone having high reliability and low manufacturing cost with a mechanical protection of the diaphragm from damage caused by extreme environment conditions.

Yet another object of the present invention is to provide an integrated MEMS microphone having diaphragm stress relief by CMOS well drive-in with a Deep Trench Oxide (DTO) process.

Yet another object of the present invention is to provide an integrated MEMS microphone having small die size by utilizing a Large Block Oxide Etch in MEMS area (LBOEM) process.

To achieve the above objects, the present invention provides a MEMS microphone, with Flip Chip Bumping package or WLP capability. The integrated MEMS microphone of the present invention combines ASIC CMOS and MEMS and uses flip chip package technology to fabricate. From the bottom up, the structure of an integrated MEMS microphone of the present invention includes a bonding wafer layer, a bonding layer, an aluminum layer, a CMOS substrate layer, an N+ implant doped silicon layer, a field oxide (FOX) layer, a plurality of implant doped silicon areas forming CMOS well, a two-tier polysilicon layer, further including an implant doped polysilicon layer and a non-doped polysilicon layer, a plurality of implant doped silicon areas forming CMOS source/drain, a gate poly layer made of polysilicon to form CMOS transistor gates, an oxide layer embedded with an interconnect contact layer, a plurality of metal layers interleaved with a plurality of via hole layers, wherein the number of metal layers and interleaving via hole layers can be adjusted according to ASIC design, a Nitride deposition layer, an under bump metal (UBM) layer and a plurality of solder spheres, said UBM layer and said solder spheres forming a flip chip bump layer. It is also worth noting that the bonding wafer layer and the CMOS substrate layer form a large back chamber area (LBCA), area of the CMOS substrate layer underneath the N+ implant doped silicon layer defines a sound hole area having a plurality of sound holes, N+ implant doped silicon layer and two-tier polysilicon layer form a small back chamber area having a plurality of non-conductive polysilicon dimples of the non-doped polysilicon layer, two-tier polysilicon layer and oxide layer form a small top chamber area having a plurality of Nitride dimples of the Nitride deposition layer, and the Nitride deposition layer includes a plurality of holes and acts as a particle filter (PF).

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic view of a conventional structure of a MEMS microphone with two-chip structure;

FIG. 2 shows a cross-sectional view of an integrated MEMS microphone with a single chip according to the present invention;

FIGS. 3A-3S show schematic views of an exemplary embodiment of a manufacturing process to fabricate the structure of integrated MEMS microphone of the present invention;

FIGS. 4A-4B show exemplary scenarios wherein the present invention is placed onto PCB substrates with top sound hole and bottom sound hole, respectively;

FIG. 5 shows a flowchart of an embodiment of the manufacturing process for the integrated MEMS microphone of the present invention;

FIG. 6 shows a flowchart of another embodiment of the manufacturing process for the integrated MEMS microphone of the present invention.

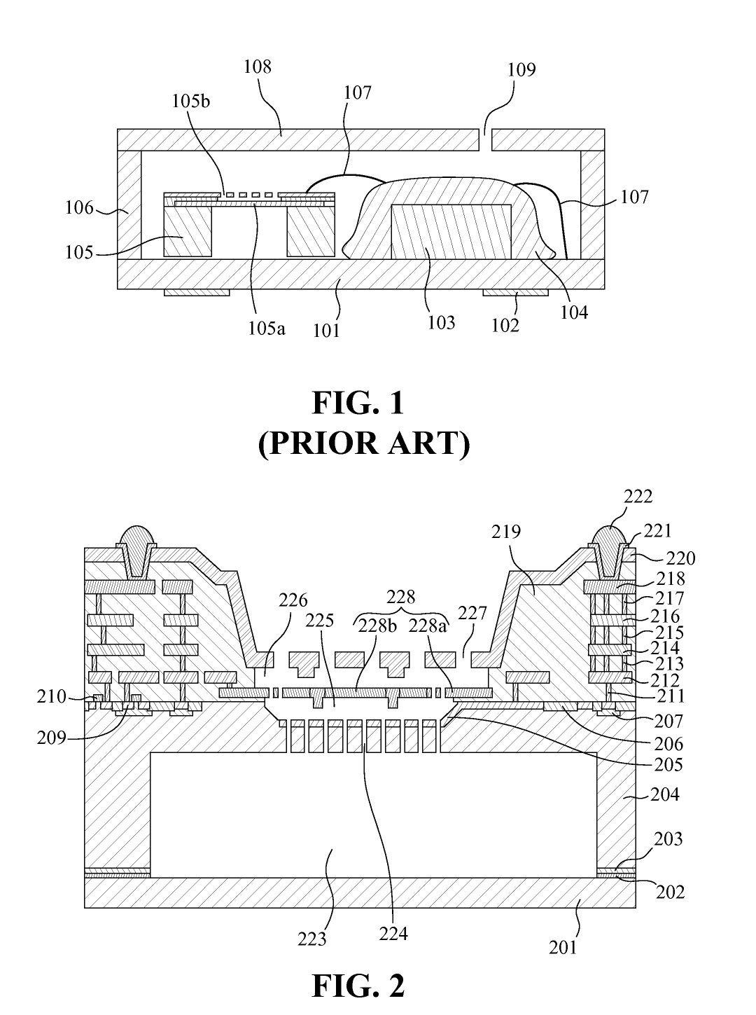

### DETAILED DESCRIPTION OF THE PREFERRED EMBODIMENTS

FIG. 2 shows a cross-sectional view of an exemplary embodiment of a MEMS device having a single chip structure fabricated to function as a MEMS microphone according to the present invention. As shown in FIG. 2, the integrated MEMS microphone of the present invention combines ASIC CMOS and MEMS and uses flip chip package technology to fabricate. From the bottom up, the structure of an integrated MEMS microphone of the present invention includes a bonding wafer layer 201, preferably heavily doped silicon layer, a bonding layer 202, an aluminum layer 203, a CMOS substrate layer 204, an N+ implant doped silicon layer 205, a field oxide (FOX) layer 206, a plurality of implant doped silicon areas 207 forming CMOS well, a two-tier polysilicon layer 208, further including a non-doped polysilicon layer 208a and an implant doped polysilicon layer 208b, a plurality of implant doped silicon areas 209 forming CMOS source/drain, a gate poly layer 210 made of polysilicon to form CMOS transistor gates, an oxide layer 219 embedded with an interconnect contact layer 211, a plurality of metal layers interleaved with a plurality of via hole layers, wherein this exemplary embodiments shows four metals and three via hole layers, including a first metal layer 212, a first via hole layer 213, a second metal layer 214, a second via hole layer 215, a third metal layer 216, a third via hole layer 217, and a fourth metal layer 218; a Nitride deposition layer 220, an under bump metal (UBM) layer 221 and a plurality of solder spheres 222, said UBM layer 221 and said solder spheres 222 forming a flip chip bump layer. It is also worth noting that bonding wafer layer 201 and CMOS substrate layer 204 form a large back chamber area (LBCA) 223, area of CMOS substrate layer 204 underneath N+ implant doped silicon layer 205 defines a sound hole area having a plurality of sound holes 224, N+ implant doped silicon layer 205 and two-tier polysilicon layer 208 form a small back chamber area 225 having a plurality of non-conductive polysilicon dimples of non-doped polysilicon layer 208a, two-tier polysilicon layer 208 and oxide layer 219 form a small top chamber area 226 having a plurality of Nitride dimples of Nitride deposition layer 220, Nitride deposition layer 220 includes a plurality of holes 227 and acts as a particle filter (PF).

For each layer, a plurality of preferred materials can be used. The following description is only for illustrative purpose, not restrictive. Equivalent materials can also be used to substitute the described materials. For example, bonding layer 202 can be made of conductive resins, germanium, BCB, metal Au compound or CuSn for wafer adhesive or eutectic bonding purpose. Aluminum layer 203 an also be made of oxide, instead of aluminum. CMOS substrate layer 204 is a P-doped CMOS substrate. Field oxide (FOX) layer 206 can be made of SiO₂ oxide, and a plurality of implant doped silicon areas 209 forms CMOS source/drain. Said CMOS wells, said CMOS transistor sources/drains and said CMOS gates (i.e., gate poly layer 210) form CMOS transistors. Interconnect contact layer 211, first via hole layer 213, second via hole layer 215, and third via hole layer 217 are preferably made of, such as, Ti/TiN/CVD-W. First metal layer 212, second metal layer 214, third metal layer 216, and fourth metal layer 218 are made of CMOS metals, such as, TiN/Cu/TiN or TiN/AlSi/TiN. It is worth noting that the number of said plurality of metals layers and via hole layers can be adjusted according to ASIC design requirements, and said plurality of metal layers with interleaved via hole layers collectively form a scribe seal. Nitride deposition layer 220 can be made of, such as, Si₃N₄ silicon Nitride. UBM layer 221 is preferably Al/NiV/Cu, solder spheres 222 can be made of, such as, Sn. In addition, two-tier polysilicon layer 208 forms a diaphragm. The diaphragm includes a plurality of holes so that small back chamber area 225 and small top chamber area 226 are connected through the holes of the diaphragm. Similarly, sound holes 224 of the sound hole area also connects small back chamber area 225 and large back chamber area 223. Non-doped polysilicon layer 208a forms a plurality of non-conductive polysilicon dimples protruding into small back chamber area 225, and Nitride layer 220 forms a plurality of Nitride dimples protruding into small top chamber area 226. As aforementioned, Nitride layer 220 above the diaphragm includes a plurality of holes so that Nitride layer 220 acts as a particle filter to filter out the particles in the airflow from outside.

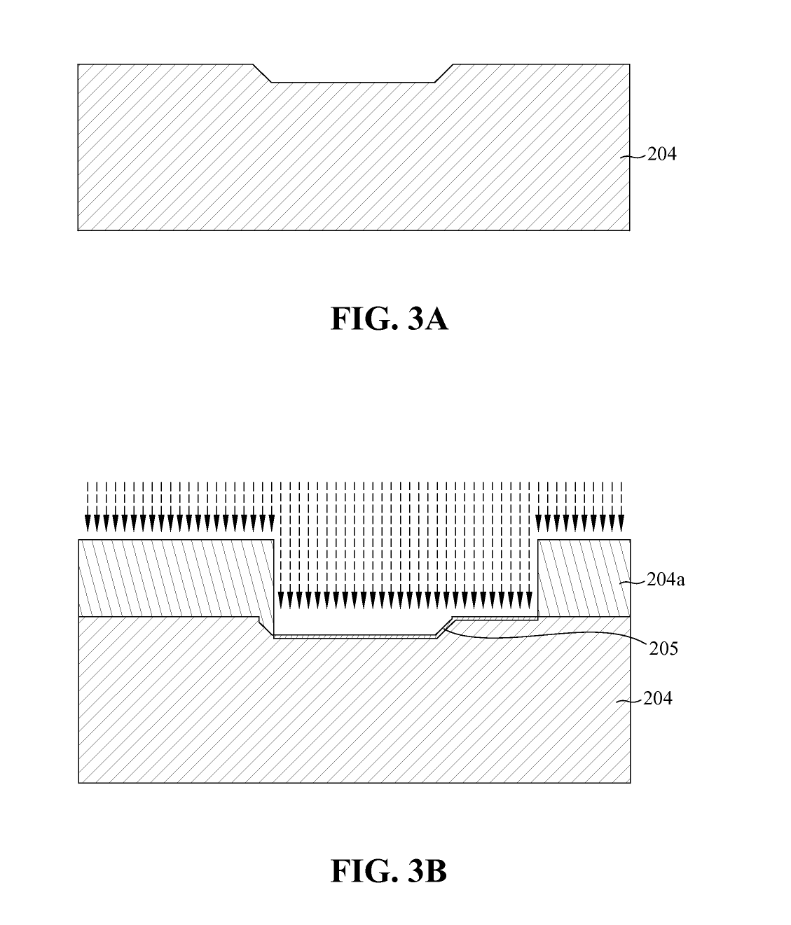

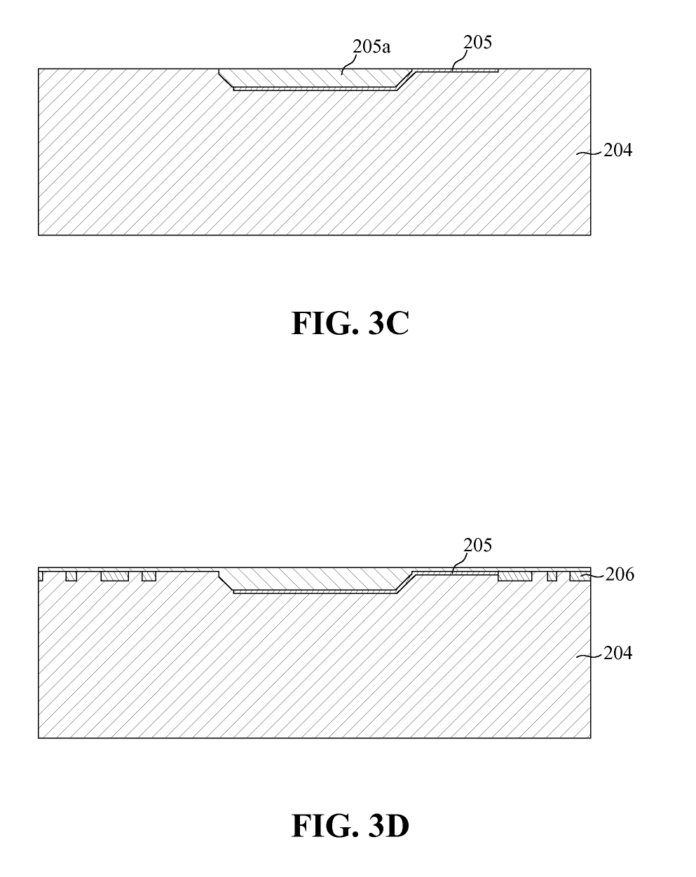

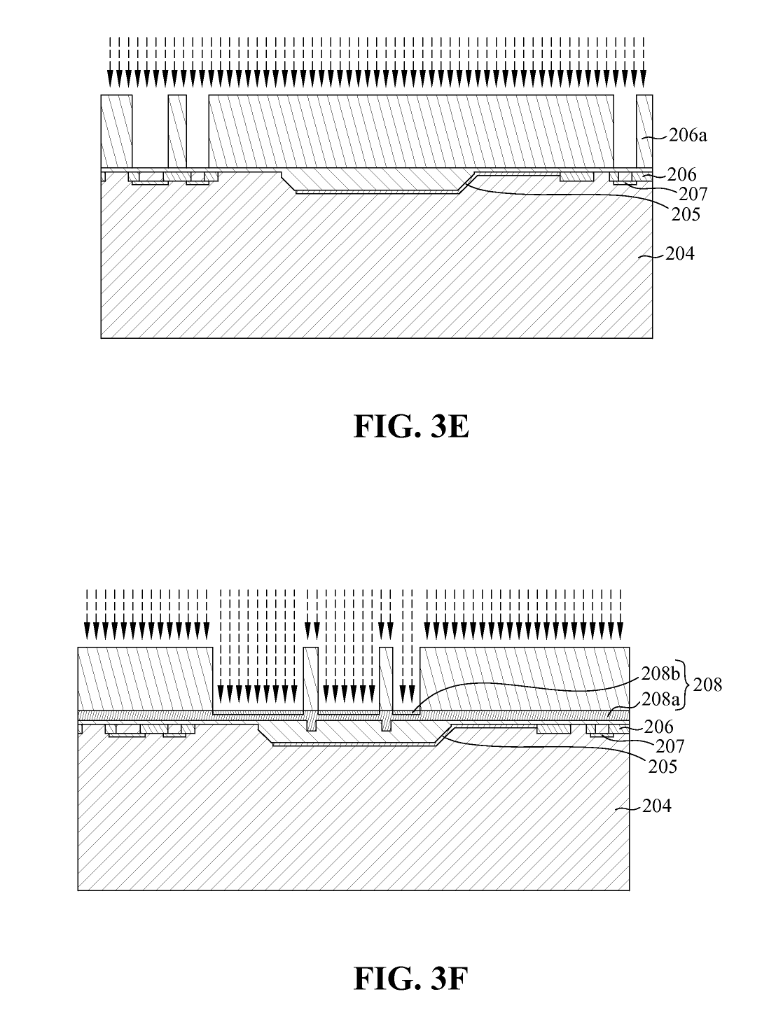

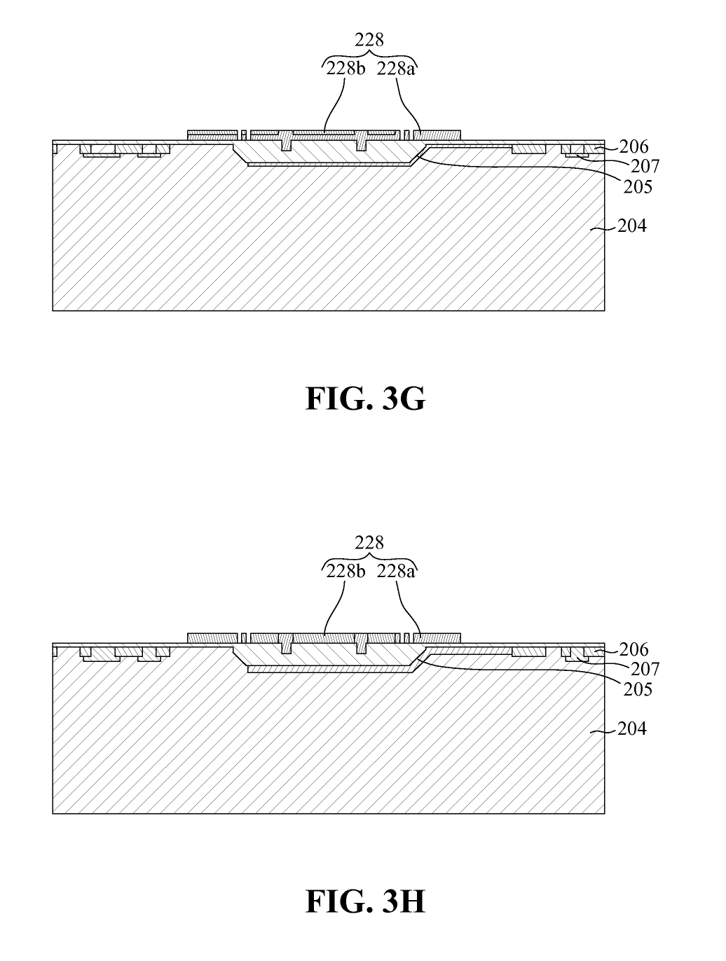

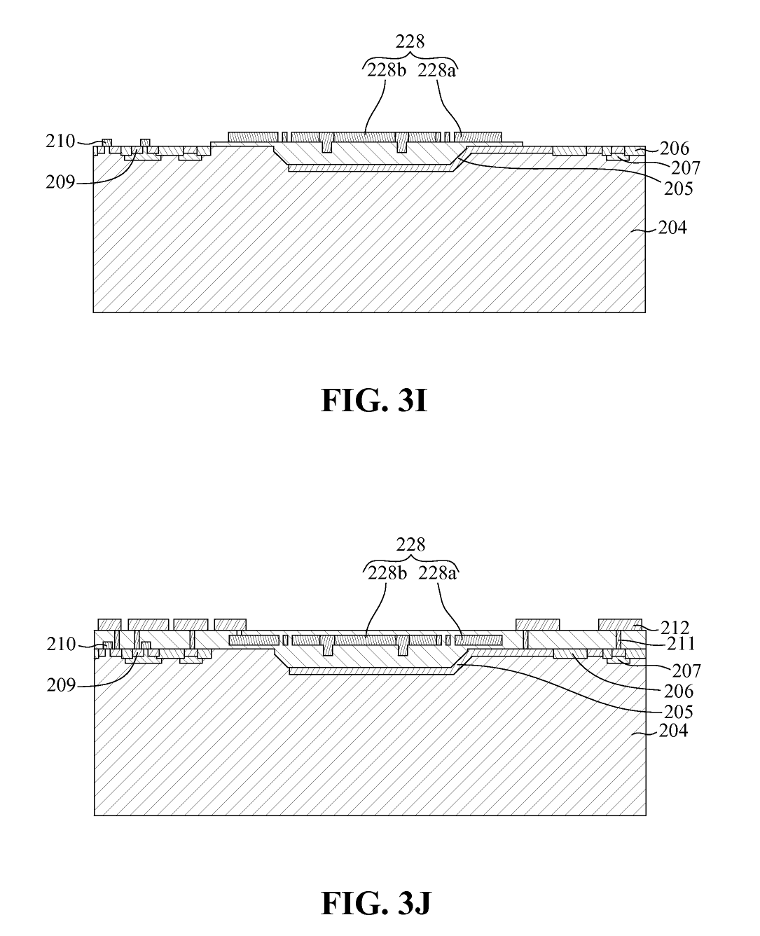

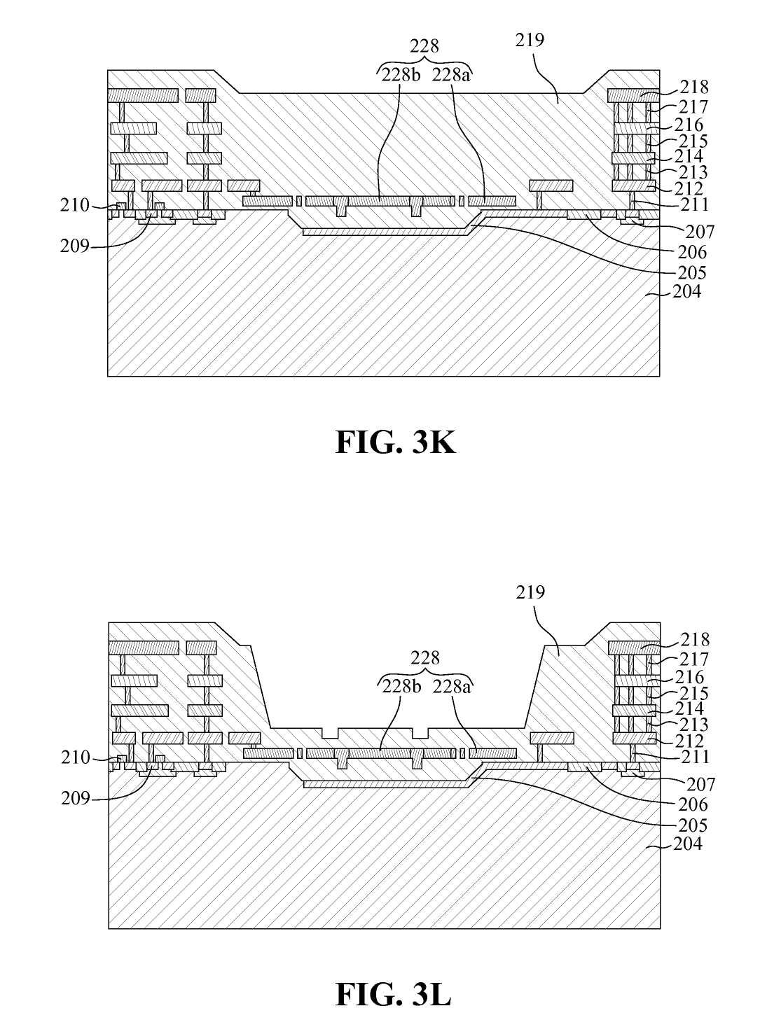

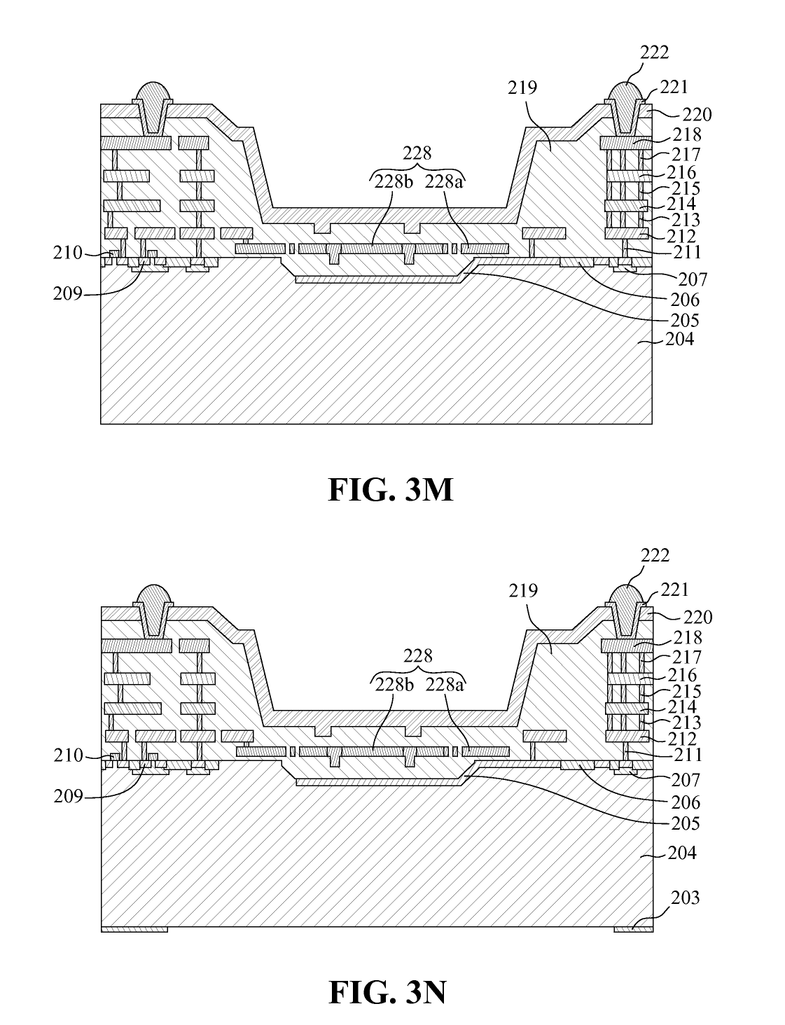

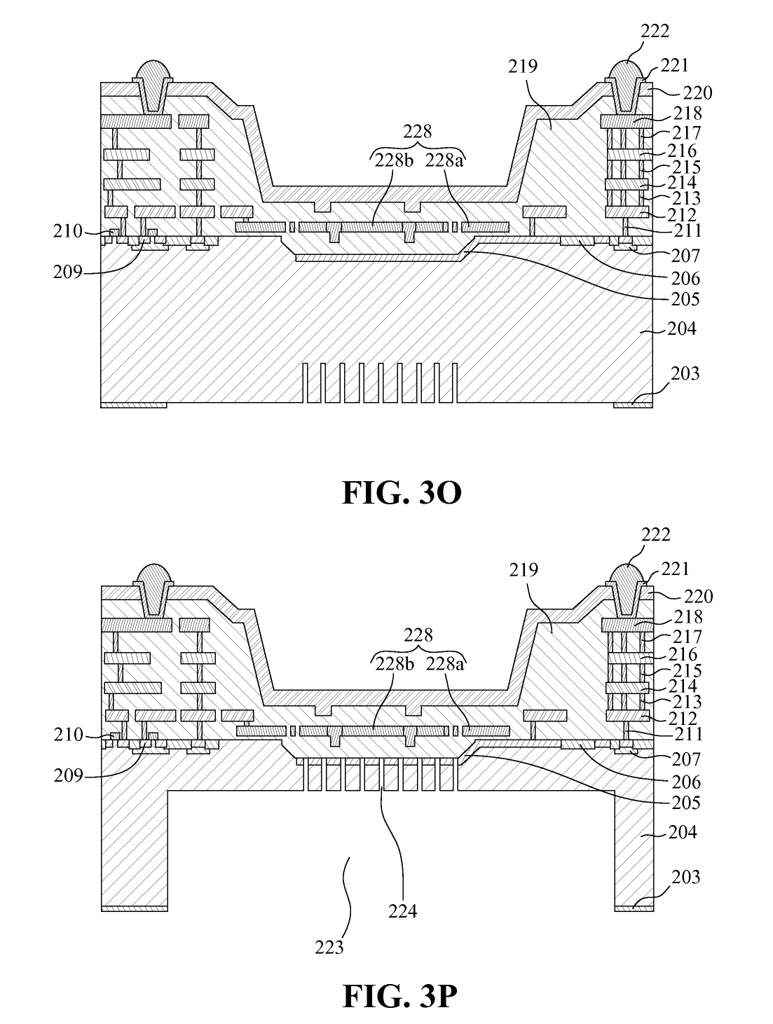

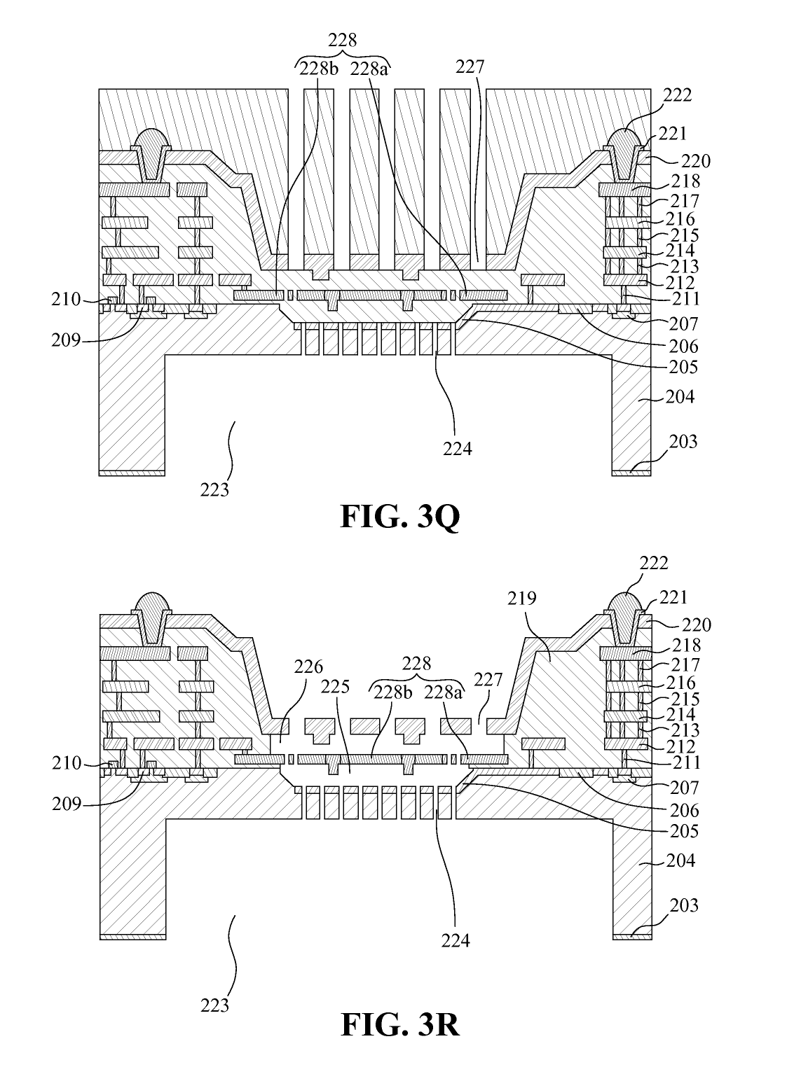

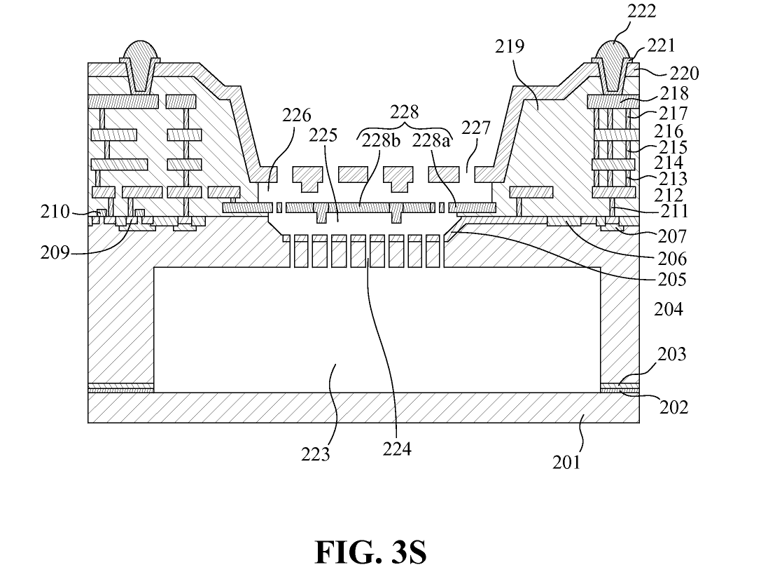

It is also worth noting while the aforementioned structure in FIG. 2 is described from the bottom up, the process to manufacture such a structure may not be from the bottom up as Flip Chip package technology is used in the preset invention. FIGS. 3A-3S show schematic views of an embodiment of a manufacturing process able to fabricate the structure of integrated MEMS microphone of the present invention. However, the process and constituting steps shown in FIGS. 3A-3S are only illustrative, instead of restrictive. Integrated MEMS microphones manufactured in other processes are also within the scope of the structure of integrated MEMS microphone of the present invention.

FIG. 3A shows a silicon substrate wafer 204 after wet silicon etches in MEMS area, which is the first step of the MEMS Deep Trench Oxide (DTO) process. The depth of silicon etch defines a gap between two capacitor plates of a MEMS capacitive microphone device according to the present invention. The depth of silicon etch is preferably around 1-3 um. FIG. 3B shows a schematic view that a photo resist pattern 204a is then used for a selective N+ ion implantation doping to form an N+ implant doped silicon layer 205, and thus form N+P junction with P− substrate 204. N+ implant doped silicon layer 205 serves as a bottom plate electrode of MEMS device. FIG. 3C shows that N+ implant doped silicon layer 205 is offset from recessed silicon area 205a. The purpose of the offset is to isolate mechanical MEMS function and electrical MEMS function such that the electrical function is optimized without limitation by the mechanical purpose of the MEMS device, whose objective will become clearer in a later description. As shown in FIG. 3C, an LPCVD thick oxide deposition of around 1-3 um and then oxide Chemical Mechanical Polish (CMP) process are performed. At the end of FIG. 3C, the MEMS DTO process is completed. The N+ ion can be Arsenic or Phosphorus or a combination of both.

In FIG. 3D, the wafer is then going through CMOS Shallow Trench Isolation (STI) process to form Field Oxide (FOX) layer 206 in the CMOS area. In the present invention, the aforementioned MEMS DTO process is to form deep trench oxide in MEMS area and the STI process is to form shallow trench oxide isolation in CMOS area. In FIG. 3E, a CMOS well photo resist pattern 206a with high energy ion implantation is performed to form CMOS wells 207. FIG. 3F shows a view after removing photo resist pattern 206a, and then non-doped polysilicon layer 208a is deposited for forming MEMS membrane, preferable 0.3-1.0 um, followed by selective ion implantation (implant doped polysilicon layer 208b) to dope the diaphragm for mechanical/electrical isolation. Implant doped polysilicon layer 208b and non-doped polysilicon layer 208a collectively form two-tier polysilicon layer 208, which acts as a diaphragm of the MEMS microphone of the present invention. FIG. 3G shows a view after the diaphragm is patterned and etched with a photo resist pattern, followed by photo resist removal. FIG. 3G shows the diaphragm includes oxide release openings in the diaphragm area. In FIG. 3H, a CMOS high temperature well drive-in process, usually 1000-1100° C. for 3-4 hours, is performed to complete CMOS wells 207. Since the polysilicon membrane is deposited on top of DTO and ion implanted with dopants prior to the CMOS high temperature well drive-in, the high temperature of CMOS well drive-in process will anneal the implant doped polysilicon membrane. Because the high temperature anneal also significantly reduces the polysilicon mechanical stress, the present invention uses the CMOS high temperature well drive-in process to obtain low stress diaphragms, a preferred polysilicon mechanical property for MEMS applications. The same high temperature also anneals the implanted N+ ion in FIG. 3B to form N+ junction with P− substrate with N+ implant doped silicon layer 205 serving as the capacitor bottom plate. The DTO process has thus served two key purposes: (a) defining the distance between capacitor plates and thus capacitance, and (b) allowing high temperature CMOS well drive-in to perform diaphragm stress relief by holding implanted diaphragm on top of surface.

As shown in aforementioned FIG. 3F, the ion implantation on the diaphragm is offset from the DTO area. The purpose of the offset ion implantation is to reduce the parasitic capacitance of the capacitor plates. The un-doped areas of the capacitor plates are non-conductive and having properties of a dielectric. The selective ion implantation doping adjusts the distance of the conductive area of the top and bottom capacitor plates in horizontal direction, so that the parasitic capacitance is minimized while the effective capacitance of the conductive plates is maximized. With proper layout of the implantation layer to dope the electrodes of the MEMS capacitor plates, the parasitic coupling capacitance between the two electrodes can be significantly reduced to close to zero, and active moving membrane capacitance becomes a dominant capacitance of the entire MEMS capacitor. Thus, by performing the ion implantation on the diaphragm, the mechanical purpose of holding the diaphragm at the edge is achieved as shown in FIG. 3H. It is worth noting that the N+ implant doped polysilicon is used as an example for the diaphragm, however, P+ Boron doped poly silicon can be used as well when deems necessary for the mechanical property of the polysilicon membrane.

Remaining oxides on the CMOS area are then patterned and etched away. A high quality gate oxide is thermally grown, then followed with poly silicon deposition to form gate poly layer 210 is then patterned and etched, followed by transistor source/drain implant and anneal to form CMOS source/drain 209; hence CMOS transistors are complete, as shown in FIG. 3I. The resulting wafer is then deposited with CMOS Inter-Level-Oxide (ILD) and CMOS ILD oxide planarization is performed before the formation of contact layer 211 and first metal layer 212, as shown in FIG. 3J. Both top plate doped polysilicon (layer 208b) and bottom plate N+ electrodes (layer 205) are contacted through interconnect contact layer 211 with first metal layer 212. In FIG. 3K, the wafer is then going through CMOS interconnect process from second metal layer 214 to fourth metal layer 218 with CMOS Multi-Level-Oxide (MLD), i.e., via hole layers 213, 215 and 217, in between metal layers. The differential capacitance between the two capacitor plates (layers 205 and 208b) is fed to the ASIC input terminal through the first metal layer (layer 212) to fourth metal layer (layer 218) connecting schemes through interleaving via hole layers. At the end of this step, metal layers and interleaving via hole layers are embedded inside an oxide layer 219.

In FIG. 3L, the MEMS large area oxide is patterned and etched, with a remaining oxide thickness above diaphragm area being around 2 to 3 um. Also included in FIG. 3L is the plurality of small holes oxide etch to form nitride dimples after successive Protective Overcoat (PO) nitride deposition, similar to the process forming poly silicon dimples in FIG. 3F. The large area oxide etch is to reduce the chip size by the reduction of the lateral oxide encroachment happened during the final wet oxide release process. Since thick oxide release requires more time and more lateral encroachment and thus larger MEMS microphone device area are needed. FIG. 3M shows a view that a Protective Overcoat (PO) silicon nitride deposition to form Nitride deposition layer 220, and flip chip bumping process, including forming UBM layer 221 and solder spheres 222, is then performed to complete a CMOS circuit with a wafer level package (WLP) capability. The process is then switched to the backside silicon substrate bottom surface. Although the current demonstration includes solder sphere 222 in FIG. 3M, it is also desirable to form the solder sphere 222 onto UBM until after the MEMS oxide release process in FIG. 3R, so that the photo resist thickness in FIG. 3Q (for the MEMS oxide release pattern) can be reduced without the height of solder sphere. Alternatively, a conformal photo resist coating process by spray coating techniques in which uniform photo resist thickness is coated along the top surface of the wafer can be used and thus elimination of the thick photo resist problem in FIG. 3Q is achieved.

FIG. 3N shows a view of silicon etch hard mask materials being deposited at the backside of silicon substrate and pattern etched to form Aluminum layer 203. The hard mask materials has high selectivity during silicon etch, materials such Aluminum or oxide are preferable. FIG. 3O shows sound holes ICP silicon pattern etch with silicon etch depth of around 30 um-100 um to form sound hole area (SHA). Then a large back chamber etch is performed with hard mask to form LBCA 223. The LBCA etch step etches the previously photo resist defined and etched SHA simultaneously with etching stop at the bottom DTO oxide, with sound holes 224 in sound hole area underneath the DTO. The resulting structure is as shown in FIG. 3P. In FIG. 3Q, a top side particle filter (or oxide release hole) is formed by patterning and etching performed with photo resist pattern on CMOS top surface of the Nitride deposition layer 220. FIG. 3Q shows a structure with nitride layer etch to form plurality of holes 227 serving as particle filters (PF) and oxide release holes. An oxide release process is then performed on the structure of FIG. 3Q, with the resulting structures as shown in FIG. 3R after resist removal, wherein oxide surrounding diaphragm is released to form small top chamber area 226 and small back chamber area 225. Nitride deposition layer 220 is a non-conductive dielectric, and serves several purposes in the present invention. For example, holes 227 in nitride deposition layer 220 serve as particle filters for the diaphragm after device formation and serve as wet chemical flow passages for the purpose of oxide release during the process of forming the device. Nitride deposition layer 220 with dimples serve as a motion stop to prevent the thin diaphragm from damage due to too much excursion from extreme sound pressure or high acceleration drop of the device. The extreme excursion of the diaphragm in the opposite direction is protected by the silicon under deep trench oxide. Thus, a structure made by the present invention provides mechanical protection to the diaphragm from damage due to extreme environmental conditions. FIG. 3S shows a view wherein a bonding wafer layer 201 is wafer-bonded with adhesive wafer bonding or eutectic bonding technology by bonding layer 201 to the bottom side of the structure of FIG. 3R to form a large back chamber area (LBCA) 223 between the sound holes area (SHA) and the bonded silicon wafers. An integrated CMOS MEMS microphone with flip chip WLP capability and ion implantation for mechanical/electrical isolation of MEMS device, diaphragm stress relief by CMOS well drive-in, and mechanical protection of the diaphragm from damage due to extreme environmental conditions and wafer bonding technology is then formed and completed.

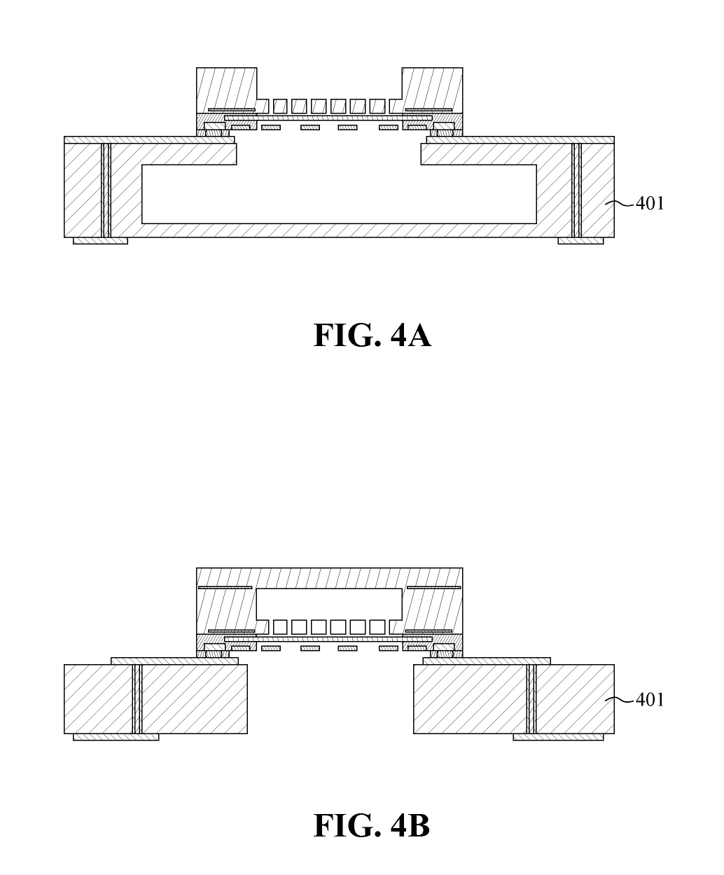

FIGS. 4A and 4B shows schematic view of two actual applications of an integrated MEMS microphone of the present invention respectively. As shown in FIG. 4A, an integrated MEMS microphone of the structure in aforementioned FIG. 3R with a back chamber formed by a PCB 401 with sound holes on top. FIG. 4B shows a schematic view of an integrated MEMS microphone of the structure in aforementioned FIG. 3S attached to a PCB 401 with bottom sound holes.

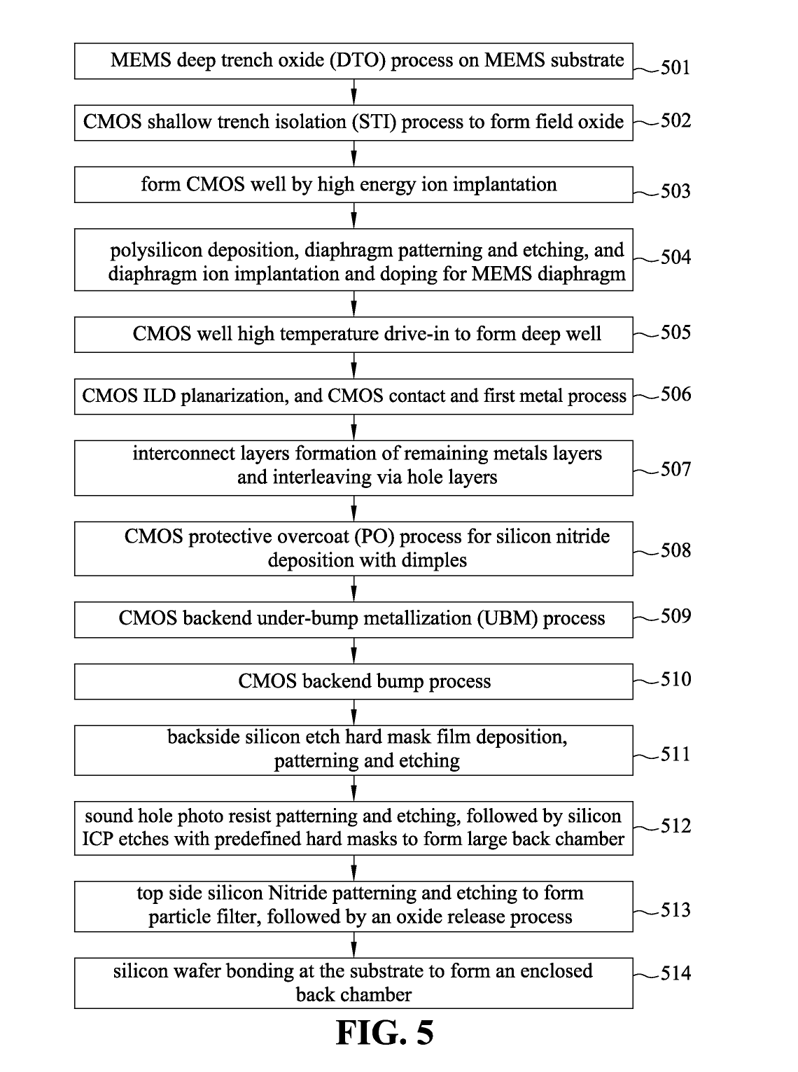

FIG. 5 shows a flowchart of an exemplary process for manufacturing the integrated MEMS microphone of the present invention. As shown in FIG. 5, step 501 is to execute a MEMS deep trench oxide (DTO) process on a MEMS substrate, further including the steps of: silicon recessed wet etch; photo resist pattern for selective N+ ion implantation to form junction with P-substrate for bottom plate electrode and mechanical/electrical isolation; and LPCVD oxide deposition and Chemical Mechanical Polish (CMP) to fill the MEMS silicon recessed area. Step 502 is to execute a CMOS shallow trench isolation (STI) process to form field oxide. Step 503 is to form CMOS well by high energy ion implantation. Step 504 is to perform polysilicon deposition, diaphragm ion implantation and doping for MEMS diaphragm to achieve the effect of diaphragm electrical connection and mechanical/electrical isolation, as well we to perform diaphragm patterning and etching. Step 505 is to perform CMOS well high temperature drive-in to form deep well. It is worth noting that the high temperature will also anneal the implant doped polysilicon membrane for stress relief; hence, a low-stress diaphragm can be obtained. Step 506 is to perform CMOS ILD planarization and to perform CMOS contact and first metal process. Step 507 is to execute interconnect layers formation of remaining metals layers and interleaving via hole layers, such as, second metal layer, third metal layer and fourth metal layer and via hole layers of FIG. 2. Step 508 is to perform a CMOS protective overcoat (PO) process for silicon nitride deposition with dimples. Step 509 is to perform a CMOS backend under-bump metallization (UBM) process. Step 510 is to perform a CMOS backend bump process. Step 511 is to perform backside silicon etch hard mask film deposition, patterning and etching to form an aluminum or silicon oxide layer. Step 512 is to perform sound hole photo resist pattern and etch, followed by silicon ICP etches with predefined hard masks to form large back chamber. Step 513 is to perform top side silicon Nitride patterning and etching, or to reduce photo resist thickness by using a consistent photo resist coating process with spray coating technique to pattern and etch the top side silicon Nitride, to form particle filter, followed by an oxide release process. Step 514 is to perform silicon wafer bonding at the substrate to form an enclosed back chamber.

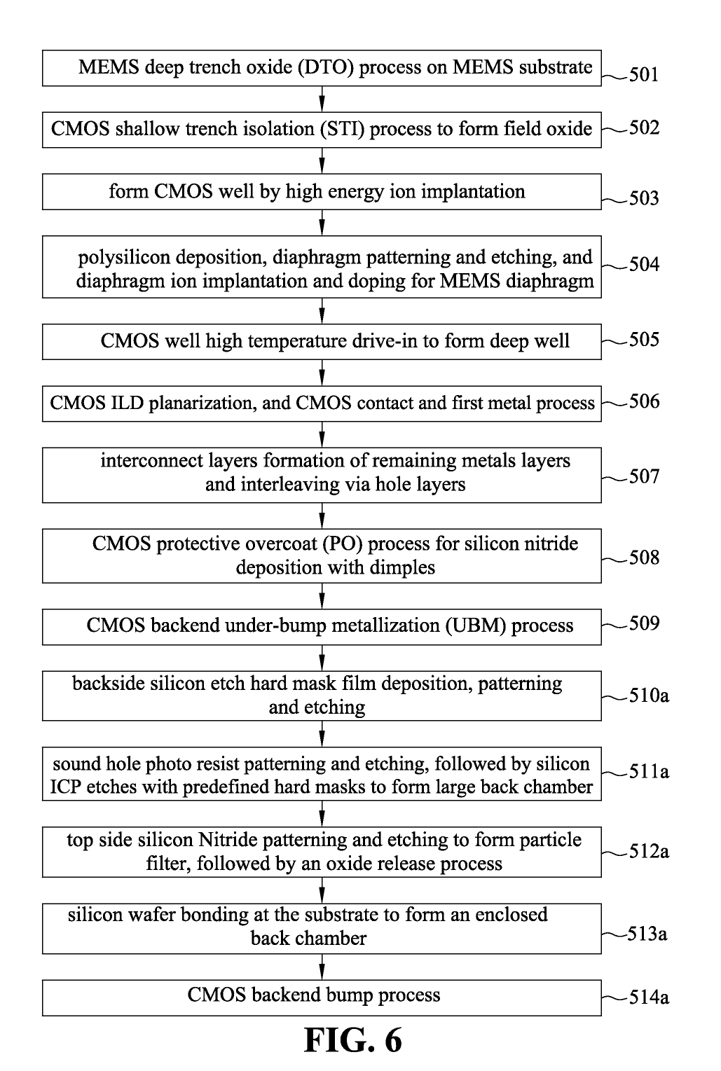

However, in the above manufacturing process, the thickness of the photo resist is too high in step 513 due to the height of the solder ball; therefore, the process may be adjusted to avoid such a condition, as shown in FIG. 6. FIG. 6 shows a flowchart of another embodiment of the manufacturing process for the integrated MEMS microphone of the present invention. As shown in FIG. 6, steps 501-509 are the same as steps 501-509 of first embodiment in FIG. 5, and the description will not be repeated. Subsequent step 510a is to perform backside silicon etch hard mask film deposition, patterning and etching to form an aluminum or silicon oxide layer. Step 511a is to perform sound hole photo resist pattern and etch, followed by silicon ICP etches with predefined hard masks to form large back chamber. Step 512a is to perform top side silicon Nitride patterning and etching to form particle filter, followed by an oxide release process. Step 513a is to perform silicon wafer bonding at the substrate to form an enclosed back chamber. Step 514a is to perform a CMOS backend bump process. Comparing the two embodiments in FIG. 5 and FIG. 6 respectively, it is shown that the two embodiments differ in that the embodiment in FIG. 6 performs steps 511, 512, 513, and 514, and then step 510 of CMOS backend bump process. As such, the yield rate is improved.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An integrated MEMS microphone with mechanical electrical isolation, comprising, from bottom up:
a bonding wafer layer;
a bonding layer;
an aluminum layer;
a CMOS substrate layer, further comprising a large back chamber area;
an N+ implant doped silicon layer;
a field oxide (FOX) layer;
a plurality of implant doped silicon areas forming CMOS wells,
a second ion implant doped silicon layer, forming CMOS source/drain;
a two-tier polysilicon layer, further including an implant doped polysilicon layer and a non-doped polysilicon layer, having a plurality of non-conductive polysilicon dimples, serving as a diaphragm, forming a small back chamber with said N+ implant doped silicon layer;
a gate poly layer, made of polysilicon to form CMOS transistor gates, said CMOS wells, said CMOS transistor sources/drains and said CMOS gates forming CMOS transistors;
an oxide layer, embedded with an interconnect contact layer, a plurality of metal layers interleaved with a plurality of via hole layers, said interconnect contact layer providing contacts to said CMOS transistors;
a Nitride deposition layer, having a plurality of holes and a plurality of Nitride dimples, serving as a particle filter, forming a small top chamber with said two-tier polysilicon layer;
an under bump metal (UBM) layer; and
a plurality of solder spheres, said UBM layer and said solder spheres forming a flip chip bump layer;
wherein said CMOS substrate layer having a recessed silicon area, said an N+ implant doped silicon layer serving as a bottom plate of a capacitor and said implant doped/un-doped composition polysilicon layer serving as a top plate of said capacitor, a plurality of sound holes formed in said N+ implant doped silicon layer and area underneath to connect said small back chamber and said large back chamber.

2. The integrated MEMS microphone as claimed in claim 1, wherein number of said plurality of metal layers and number of said interleaving via hole layers can be adjusted.

3. The integrated MEMS microphone as claimed in claim 1, wherein said bonding layer is made of materials for wafer adhesive or eutectic bonding.

4. The integrated MEMS microphone as claimed in claim 1, wherein depth of said recessed silicon area on said CMOS substrate determines a gap of said capacitor plates.

5. The integrated MEMS microphone as claimed in claim 1, wherein said capacitor plates comprise ion implantation for electrical conductivity.

6. The integrated MEMS microphone as claimed in claim 1, wherein an isolated N+P junction is formed with said recessed silicon area of said CMOS substrate by selective ion implantation.

7. The integrated MEMS microphone as claimed in claim 1, wherein CMOS oxide area on top of MEMS is etched away to reduce the MEMS oxide release time and the lateral oxide encroachment during the oxide release and thus the chip size reduction is achieved.

8. The integrated MEMS microphone as claimed in claim 1, wherein mechanical/electrical isolation of a MEMS microphone is achieved by MEMS layers with selective ion implantation.

9. The integrated MEMS microphone as claimed in claim 1, wherein said diaphragm comprises holes to connect said small back chamber and said small top chamber.

10. A manufacturing method for forming an integrated MEMS microphone, comprising the steps of:
executing a MEMS deep trench oxide (DTO) process on a MEMS substrate;
executing a CMOS shallow trench isolation (STI) process to form field oxide;
forming CMOS well by high energy ion implantation;
performing polysilicon deposition, diaphragm patterning and etching, and diaphragm ion implantation and doping for MEMS diaphragm to achieve effect of diaphragm electrical connection and mechanical/electrical isolation, as well as, performing polysilicon diaphragm patterning and etching;
performing CMOS well high temperature drive-in to form deep well to obtain low stress diaphragm;
performing CMOS ILD planarization, and CMOS contact and first metal process;
executing interconnect layers formation of remaining metals layers and interleaving via hole layers;
performing a CMOS protective overcoat (PO) process for silicon nitride deposition with dimples;
performing a CMOS backend under-bump metallization (UBM) process;
performing a CMOS backend bump process;
performing backside silicon etch hard mask film deposition, patterning and etching;
performing sound hole photo resist patterning and etching, followed by silicon ICP etches with predefined hard masks to form large back chamber;
performing top side silicon Nitride patterning and etching to form particle filter, followed by an oxide release process; and
performing silicon wafer bonding at the substrate to form an enclosed back chamber.

11. The manufacturing method as claimed in claim 10, wherein said DTO process further comprises the steps of:
performing silicon recessed wet etch;
photo resist pattern for selective N+ ion implantation to form junction with P-substrate for bottom plate electrode and mechanical/electrical isolation; and
LPCVD oxide deposition and Chemical Mechanical Polish (CMP) to fill the MEMS silicon recessed area.

12. The manufacturing method as claimed in claim 10, wherein a Flip Chip Bumping package or WLP (Wafer Level Package) is adopted.

13. The manufacturing method as claimed in claim 10, wherein a wafer to wafer bonding technology is used for the CMOS MEMS to form an enclosed back chamber.

14. The manufacturing method as claimed in claim 10, wherein a structure is made by this invention that mechanical protection on the diaphragm film from damage due to extreme environmental conditions is provided.

15. The manufacturing method as claimed in claim 10, wherein said CMOS well high temperature drive-in also anneals implant doped polysilicon diaphragm to obtain a low-stress diaphragm.

16. The manufacturing method as claimed in claim 10, wherein said step of forming said large back chamber also forms a plurality of sound holes, and said sound holes are connected to said large back chambers.

17. The manufacturing method as claimed in claim 10, wherein said oxide release process forms a small back chamber beneath said diaphragm, and a small top chamber above said diaphragm, and said small back chamber and said small top chamber are connected through holes in said diaphragm.

18. The manufacturing method as claimed in claim 17, wherein said step of forming said large back chamber also forms a plurality of sound holes, and said small back chamber is connected to said large back chamber through said sound holes.

19. A manufacturing method for forming an integrated MEMS microphone, comprising the steps of:
executing a MEMS deep trench oxide (DTO) process on a MEMS substrate;
executing a CMOS shallow trench isolation (STI) process to form field oxide;
forming CMOS well by high energy ion implantation;
performing polysilicon deposition, diaphragm patterning and etching, and diaphragm ion implantation and doping for MEMS diaphragm to achieve effect of diaphragm electrical connection and mechanical/electrical isolation, as well as, performing polysilicon diaphragm patterning and etching;
performing CMOS well high temperature drive-in to form deep well to obtain low stress diaphragm;
performing CMOS ILD planarization, and CMOS contact and first metal process;
executing interconnect layers formation of remaining metals layers and interleaving via hole layers;
performing a CMOS protective overcoat (PO) process for silicon nitride deposition with dimples;
performing a CMOS backend under-bump metallization (UBM) process;
performing backside silicon etch hard mask film deposition, patterning and etching;
performing sound hole photo resist patterning and etching, followed by silicon ICP etches with predefined hard masks to form large back chamber;
performing top side silicon Nitride patterning and etching to form particle filter, followed by an oxide release process;
performing silicon wafer bonding at the substrate to form an enclosed back chamber; and
performing a CMOS backend bump process.
